(19) United States
(12) Patent Application Publication
(10) Pub. No.: US 2025/0087966 A1
(43) Pub. Date: Mar. 13, 2025

(54) PHOTOELECTRIC CONVERSION MODULE, PHOTOELECTRIC CONVERSION DEVICE, AND PHOTOELECTRIC CONVERSION METHOD

(71) Applicant: SHENNAN CIRCUITS CO., LTD., SHENZHEN (CN)

(72) Inventors: Hailong LIAO, SHENZHEN (CN); Guodong WANG, SHENZHEN (CN); Hua MIAO, SHENZHEN (CN)

(73) Assignee: SHENNAN CIRCUITS CO., LTD., SHENZHEN (CN)

(21) Appl. No.: 18/957,484

(22) Filed: Nov. 22, 2024

Related U.S. Application Data
(63) Continuation of application No. PCT/CN2024/090182, filed on Apr. 26, 2024.

(30) Foreign Application Priority Data
May 16, 2023 (CN) 202310555266.1

(51) Int. Cl. H01S 5/042

(52) U.S. Cl. CPC H01S 5/042

(57) ABSTRACT

A photoelectric conversion module includes an electro-optical conversion unit. The electro-optical conversion unit includes a transmitting terminal, a laser, and a bias constant current source providing a constant current to the laser. The laser is configured to convert a voltage signal to be transmitted of the transmitting terminal into an optical signal synchronized with the voltage signal. A photoelectric conversion device and a photoelectric conversion method are further provided.

### CROSS-REFERENCE TO RELATED APPLICATIONS

The present application is a continuation of International Patent Application No. PCT/CN2024/090182, filed on Apr. 26, 2024, which claims priority to Chinese Patent Application No. 202310555266.1, filed on May 16, 2023, both of which are herein incorporated by reference in their entirety.

### TECHNICAL FIELD

The present disclosure relates to the field of photoelectric conversion technologies, and in particular to a low-power consumption photoelectric conversion module, a photoelectric conversion device, and a photoelectric conversion method.

### BACKGROUND

With the advent of 5G technology and the development of Internet of Everything applications, the amount of data in data centers is increasing day by day, and the scale of the data centers is continuously expanding. It puts forward new demands for high-speed and low-power consumption interconnection technology.

The optical interconnection, with its advantages of anti-interference, high bandwidth, and high interconnection density, is widely used in the data centers. The power consumption of a key device involved, such as a photoelectric conversion device, increases with the increase of speed. A traditional photoelectric conversion device is mainly suitable for transmission over distances of 100 meters or more. In fact, the current interconnection scenarios in the data centers are mainly short-range, such as interconnections within cabinets, backplane-level interconnections, or interconnections between servers and switches, etc.

The photoelectric conversion devices in related art have significant design redundancy in the field of short-reach interconnection. Therefore, how to reduce the total power consumption of a system in the short-reach interconnection and achieve high-speed, high-density, and low-power consumption interconnection in the data centers is an urgent problem to be solved.

### SUMMARY OF THE DISCLOSURE

In a first aspect, the embodiments of the present disclosure provide a low-power consumption photoelectric conversion module. The photoelectric conversion module includes an electro-optical conversion unit. The electro-optical conversion unit includes a transmitting terminal, a laser, and a bias constant current source providing a constant current to the laser. The laser is configured to convert a voltage signal to be transmitted on the transmitting terminal into an optical signal synchronized with the voltage signal to be transmitted.

In some embodiments, the electro-optical conversion unit further includes a capacitor element. The capacitor element is disposed between the transmitting terminal and the laser, and configured to protect a signal source chip connected to the transmitting terminal.

In some embodiments, the photoelectric conversion module further includes a photoelectric conversion unit. The photoelectric conversion unit includes a receiving terminal, a photoelectric detector, and an electrical signal conversion unit connected to an output terminal of the photoelectric detector. The photoelectric detector is configured to convert the optical signal received by the receiving terminal into a current signal, and the electrical signal conversion unit is configured to convert the current signal into a voltage signal.

In some embodiments, the electrical signal conversion unit includes a sampling resistor, and the sampling resistor is connected to the output terminal of the photoelectric detector and configured to convert the current signal generated by the photoelectric detector into a single ended voltage signal.

In some embodiments, the electrical signal conversion unit further includes a first element connected to the sampling resistor, and the first element is configured to convert the single ended voltage signal into a differential voltage signal.

In some embodiments, the electrical signal conversion unit includes a second element, the second element is connected to the output terminal of the photoelectric detector and configured to directly convert the current signal output by the photoelectric detector into a differential voltage signal, and the second element includes a transimpedance amplifier.

In some embodiments, the second element includes a transimpedance amplifier, an operational amplifier, a transistor, or a MOS transistor.

In a second aspect, the embodiments of the present disclosure provide a photoelectric conversion device, and the photoelectric conversion device includes a photoelectric conversion module of any one of above embodiments in the first aspect.

In some embodiments, the photoelectric conversion device further includes an integrated chip. The integrated chip is connected to the transmitting terminal of the photoelectric conversion unit of the photoelectric conversion module, and configured for transmitting a differential voltage signal to the transmitting terminal of the photoelectric conversion module. The integrated chip is further connected to the receiving terminal of the photoelectric conversion unit of the photoelectric conversion module, and configured for processing the voltage signal generated by the photoelectric conversion module.

In some embodiments, the photoelectric conversion module is integrated on a PCB board where the integrated chip is located, and the photoelectric conversion module is connected to the integrated chip through copper trace on the PCB board.

In some embodiments, the photoelectric conversion module is integrated on a substrate to form a component with a photoelectric conversion function. The component is disposed on the PCB board where the integrated chip is located by plugging or soldering.

In some embodiments, the photoelectric conversion device further includes an optical signal transmission channel, the optical signal transmission channel is connected to a receiving terminal of the photoelectric conversion module and configured for transmitting the optical signal, and the optical signal transmission channel includes an optical fiber and an optical waveguide.

In a third aspect, the embodiments of the present disclosure provide a low-power consumption photoelectric conversion method. The photoelectric conversion method adopts a photoelectric conversion module of any one of above embodiments in the first aspect or the photoelectric conversion device of any one of above embodiments in the second aspect for photoelectric conversion.

### BRIEF DESCRIPTION OF THE DRAWINGS

In order to more clearly illustrate the technical solutions in some embodiments of the present disclosure, hereinafter, a brief introduction will be given to the accompanying drawings that are used in the description of some embodiments. Obviously, the accompanying drawings in the description below are merely some embodiments of the present disclosure. For those of ordinary skill in the art, other accompanying drawings can be obtained based on these accompanying drawings without any creative efforts.

FIG. 1 is a structural schematic view of a low-power consumption photoelectric conversion module in a first embodiment of the present disclosure.

FIG. 2 is a structural schematic view of a photoelectric conversion module in a second embodiment of the present disclosure.

FIG. 3 is a structural schematic view of a photoelectric conversion module in a third embodiment of the present disclosure.

FIG. 4 is a structural schematic view of a photoelectric conversion module in a fourth embodiment of the present disclosure.

FIG. 5 is a structural schematic view of a photoelectric conversion module in a fifth embodiment of the present disclosure.

FIG. 6 is a structural schematic view of a photoelectric conversion device in the first embodiment of the present disclosure.

### DETAILED DESCRIPTION

The solutions in some embodiments of the present disclosure are explained in detail by combining the accompanying drawings.

In the following description, for the purpose of illustration rather than limitation, the described embodiments are only a part of the embodiments of the present disclosure, and not all embodiments. Based on the embodiments in the present disclosure, all other embodiments obtained by those of ordinary skill in the art without creative effort are within the scope of the present disclosure.

The terms used in the embodiments of the present disclosure are for the purpose of describing specific embodiments only, and are not intended to limit the present disclosure. The singular forms of “one”, “a”, “an”, “said”, and “the” used in the embodiments and claims of the present disclosure are also intended to include the plural form, unless clearly indicated otherwise in the context. The term “multiple” or “plurality” generally includes at least two, but does not exclude the possibility of including at least one.

It should be understood that the term “and/or” used in the present disclosure is only used to describe a relationship between related objects, indicating that there can be three types of relationships. For example, A and/or B, which can represent: the existence of A alone, the existence of A and B at the same time, and the existence of B alone. In addition, the character “/” in the present disclosure generally indicates that the object before the character “/” and the object after the character “/” are in an “or” relationship.

It should be understood that the terms “including”, “comprising” or any other variation used in the present disclosure are intended to cover non-exclusive inclusions. Therefore, a process, a method, a product, or a device that includes a series of elements not only includes those elements, but also includes other elements not explicitly listed, or also includes elements inherent to such process, method, product, or device. Without further limitations, the elements defined by the statement “including . . . ” or “comprising . . . ” do not exclude the existence of other identical elements in the process, the method, the product, or the device that includes the said elements.

It should be noted that all directional indications (such as up, down, left, right, front, rear, or the like) in some embodiments of the present disclosure are only configured to explain a relative position relationship between components in a specific posture (as shown in the accompanying drawings), a motion situation between the components in the specific posture (as shown in the accompanying drawings), or the like. When the specific posture is changed, the directional indication is also changed accordingly.

In addition, the terms “first” and “second” in the present disclosure are only configured to describe and cannot be understood as indicating or implying relative importance or implicit indicating the quantity of technical features indicated. Therefore, features that are defined as “first” and “second” can explicitly or implicitly include at least one of these features.

The reference to “embodiments” in the present disclosure means that, specific features, structures, or characteristics described in conjunction with some embodiments can be included in at least one embodiment of the present disclosure. The phrase appearing in various positions in the specification does not necessarily refer to the same embodiment, nor is it an independent or alternative embodiment that is mutually exclusive with other embodiments. Those of ordinary skill in the art explicitly and implicitly understand that the embodiments described in the present disclosure can be combined with other embodiments.

The present disclosure provides a low-power consumption photoelectric conversion module, a photoelectric conversion device, and a photoelectric conversion method, thereby achieving short-reach and low-power consumption photoelectric conversion.

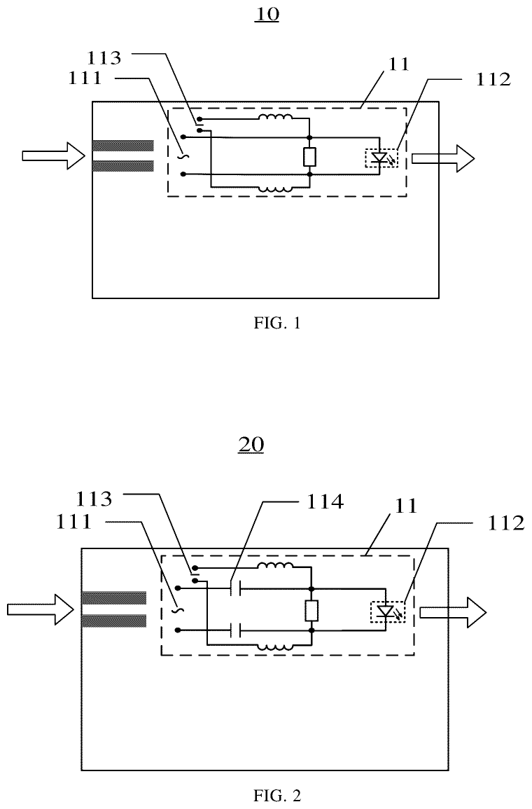

The present disclosure provides a low-power consumption photoelectric conversion module 10, as shown in FIG. 1, FIG. 1 is a structural schematic view of a low-power consumption photoelectric conversion module 10 in a first embodiment of the present disclosure. As shown in FIG. 1, the photoelectric conversion module 10 at least includes an electro-optical conversion unit 11. The electro-optical conversion unit 11 is configured to convert an electrical signal into an optical signal. The electro-optical conversion unit 11 includes a transmitting terminal 111, a laser 112, and a bias constant current source 113. The transmitting terminal 111 is configured to receive the electrical signal. The laser 112 is connected to the transmitting terminal 111 and configured for directly converting a differential voltage signal received by the transmitting terminal 111 into the optical signal synchronized with the differential voltage signal. The bias constant current source 113 is configured to provide a constant current to the laser 112, so that the laser 112 operates in a linear light-emitting range, ensuring that the laser 112 can stably emit light. When the laser 112 receives the differential voltage signal, the laser 112 can emit a light based on the differential voltage signal, the brightness of the light is different from that of a stable light emitted by the laser 112, and the light can synchronously change with the differential voltage signal to form the optical signal, thereby transmitting the signal. A voltage signal to be transmitted of the transmitting terminal 111 can be the differential voltage signal emitted by an integrated chip or a single ended voltage signal after processing, which is not limited here. The transmitting terminal 111 refers to one terminal connected to the integrated chip, and the transmitting terminal 111 is configured for receiving and transmitting the electrical signal.

In the present embodiment, the bias constant current source 113 can provide the stable constant current to the laser 112, so that the laser 112 operates in the linear light-emitting range. Then, the transmitting terminal 111 receives the differential voltage signal, and the laser 112 generates the optical signal synchronized with the differential voltage signal under the influence of the differential voltage signal. The low-power consumption signal transmission is achieved through the optical signal. By disposing the bias constant current source 113 that provides the constant current to the laser 112, the laser 112 can operate at a stable static operating point, so that the laser 112 can directly convert the differential voltage signal into the optical signal synchronized with the differential voltage signal when receiving the differential voltage signal. In the present embodiment, an inductor element is further disposed between the bias constant current source 113 and an input terminal of the laser 112. The inductor element is configured to filter alternating current (AC), so that the constant current is provided to the laser 112, which is not limited here.

The effects of the present embodiment are as follows. By disposing the laser 112 and the bias constant current source 113 that provides the constant current to the laser 112, the received differential voltage signal can be directly converted into the optical signal. Therefore, a module, such as a clock and data recovery (CDR) circuit, an equalizer (EQ), a current-driven circuit or the like, that is included in a conventional laser drive circuit can be omitted. Therefore, the light-emitting power of the laser 112 can be reduced, and the power consumption of the electro-optical conversion unit 11 can be reduced.

The present disclosure further provides a second type of low-power consumption photoelectric conversion module 20, as shown in FIG. 2, FIG. 2 is a structural schematic view of a photoelectric conversion module 20 in a second embodiment of the present disclosure. As shown in FIG. 2, the photoelectric conversion module 20 further includes a capacitor element 114, and the capacitor element 114 is disposed on an input terminal (i.e., the transmitting terminal 111) of the electro-optical conversion unit 11. In some embodiments, the capacitor element 114 is disposed between the transmitting terminal 111 and the laser 112. In some embodiments, the capacitor element 114 is disposed between the transmitting terminal 111 and the bias constant current source 113, so as to prevent a high voltage, static electricity, etc. of the bias constant current source 113 from returning to the chip that emits the differential voltage signal to the laser 112, thereby avoid damage to the chip. In the present embodiment, the capacitor element 114 blocks direct current while allowing the alternating current to pass through, thereby transmitting the differential voltage signal to the input terminal of the laser 112, and preventing the signal of the bias constant current source 113 from being transmitted to the transmitting terminal 111. The present embodiment is a preferred embodiment, and in other embodiments, other protective components can be provided or not provided, which is not limited here.

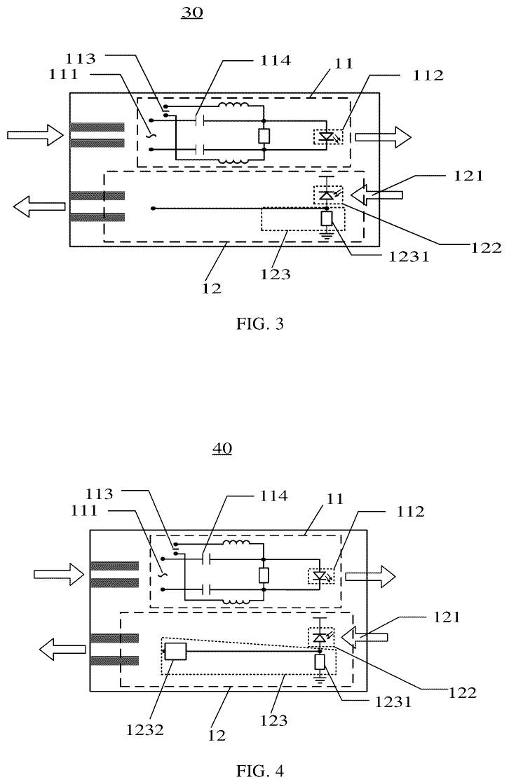

The present disclosure further provides a third type of low-power consumption photoelectric conversion module 30, as shown in FIG. 3, FIG. 3 is a structural schematic view of a photoelectric conversion module 30 in a third embodiment of the present disclosure. As shown in FIG. 3, in addition to the structures of the above embodiments, the photoelectric conversion module 30 further includes a photoelectric conversion unit 12. The photoelectric conversion unit 12 is configured to convert the optical signal into the electrical signal. In some embodiments, the photoelectric conversion unit 12 includes a receiving terminal 121, a photoelectric detector 122, and an electrical signal conversion unit 123 connected to an output terminal of the photoelectric detector 122. The photoelectric detector 122 is configured to convert the optical signal received by the receiving terminal 121 into a current signal. The electrical signal conversion unit 123 is configured to convert the current signal into the voltage signal, so that the integrated chip can receive and process the voltage signal. The voltage signal includes the single ended voltage signal and the differential voltage signal. The receiving terminal 121 is an optical signal receiving terminal configured for transmitting and receiving the optical signal.

In the present embodiment, the photoelectric detector 122 further includes a power supply component (not labeled in the figures) that provides a reverse bias voltage to the photoelectric detector 122, so that the photoelectric detector 122 operates in an optical guide mode, thereby improving a response rate of the photoelectric detector 122, which is not limited here.

In some embodiments, the electrical signal conversion unit 123 can only include one sampling resistor 1231. The sampling resistor 1231 is connected to the output terminal of the photoelectric detector 122. The sampling resistor 1231 is configured to convert the current signal generated by the photoelectric detector 122 into the single ended voltage signal, so that the integrated chip connected to the receiving terminal 121 of the photoelectric conversion unit 12 can receive and process the voltage signal.

In some embodiments, as shown in FIG. 4, FIG. 4 is a structural schematic view of a photoelectric conversion module 40 in a fourth embodiment of the present disclosure. As shown in FIG. 4, the electrical signal conversion unit 123 includes the sampling resistor 1231 and a first element 1232 connected to an output terminal of the sampling resistor 1231. The first element 1232 includes the chip or the like. The first element 1232 is configured to convert the single ended voltage signal into the differential voltage signal.

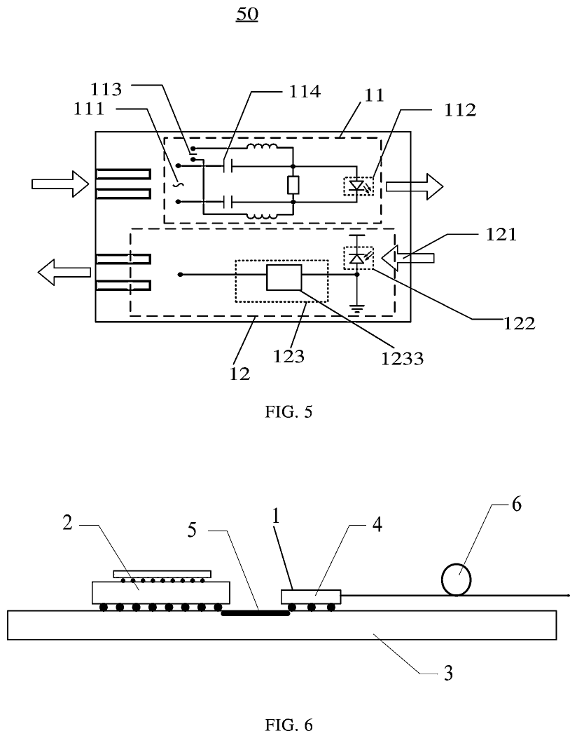

In some embodiments, as shown in FIG. 5, FIG. 5 is a structural schematic view of a photoelectric conversion module 50 in a fifth embodiment of the present disclosure. As shown in FIG. 5, the electrical signal conversion unit 123 includes a second element 1233. The second element 1233 is connected to the output terminal of the photoelectric detector 122. The second element 1233 is configured to directly convert the current signal output by the photoelectric detector 122 into the differential voltage signal, so that the integrated chip can directly perform arithmetic processing. The second element 1233 includes an element with the function of converting current into voltage, amplifying the voltage, or converting the single ended signal into the differential signal, such as a transimpedance amplifier, an operational amplifier, a transistor, or a Metal-Oxide-Semiconductor (MOS) transistor, etc.

The present disclosure further provides a photoelectric conversion device, and the photoelectric conversion device includes a photoelectric conversion module 1, and the photoelectric conversion module 1 is any one of the photoelectric conversion modules 10, 20, 30, 40, and 50 of the above embodiments.

In the present embodiment, the photoelectric conversion device further includes an integrated chip 2, as shown in FIG. 6, FIG. 6 is a structural schematic view of a photoelectric conversion device in the first embodiment of the present disclosure. As shown in FIG. 6, the photoelectric conversion device includes the photoelectric conversion module 1 and the integrated chip 2 connected to the photoelectric conversion module 1. The integrated chip 2 is connected to the transmitting terminal 111 of the photoelectric conversion module 1 and configured to transmit the differential voltage signal to the transmitting terminal 111 of the photoelectric conversion unit 11 of the photoelectric conversion module 1. The photoelectric conversion device further includes a photoelectric conversion unit 12. The integrated chip 2 is connected to the photoelectric conversion unit 12 of the photoelectric conversion module 1 and configured for processing the voltage signal generated by the photoelectric conversion module 11.

In some embodiments, the integrated chip 2 is disposed on a printed circuit board (PCB) board 3, and the photoelectric conversion module 1 is integrated on a substrate to form a component 4 with a photoelectric conversion function. The component 4 is disposed on the PCB board 3 where the integrated chip 2 is located by plugging or soldering. In some embodiments, the photoelectric conversion module 1 is disposed as a separate element on the PCB board 3, which facilitates disassembly and maintenance. In some embodiments, the component 4 with the photoelectric conversion function is connected to the integrated chip 2 through copper trace 5 on the PCB board 3.

In some embodiments, various electronic components (a capacitor, the laser 112, and the photoelectric detector 122, etc.) of the photoelectric conversion module 1 are directly integrated on the PCB board 3 where the integrated chip 2 is located. The various electronic components of the photoelectric conversion module 1 are connected to each other through the copper trace 5 on the PCB board 3. The various electronic components of the photoelectric conversion module 1 are further connected to the integrated chip 2 through the copper trace 5, which is not limited here.

In some embodiments, the photoelectric conversion device further includes an optical signal transmission channel 6. The optical signal transmission channel 6 is connected to an optical transmitting terminal of the electro-optical conversion unit 11 of the photoelectric conversion module 1. In some embodiments, the optical signal transmission channel 6 is connected to the output terminal of the laser 112 and configured for emitting optical signals. The optical signal transmission channel 6 is further connected to the receiving terminal 121 of the photoelectric conversion unit 12 of the photoelectric conversion module 1, and configured for receiving the optical signal. The optical signal transmission channel 6 includes any one of the optical fiber and the optical waveguide, or both the optical fiber and the optical waveguide.

The present disclosure further provides a low-power consumption photoelectric conversion method. The low-power consumption photoelectric conversion method adopts the photoelectric conversion module 1 in any one of the above embodiments for photoelectric conversion. Alternatively, the low-power consumption photoelectric conversion method adopts the photoelectric conversion device in any one of the above embodiments for photoelectric conversion.

In some embodiments, the photoelectric conversion is as follows. The photoelectric conversion module 1 receives the differential voltage signal and converts the differential voltage signal into the optical signal through the laser 112, and the optical signal is synchronized with the differential voltage signal. The photoelectric conversion module 1 transmits the optical signal carrying the signal, so as to transmit information.

The photoelectric conversion unit 12 of the photoelectric conversion module 1 can further convert the received optical signal into the electrical signal and transmit the electrical signal to the integrated chip 2 for processing.

In the present disclosure, the received differential voltage signal is directly converted into the optical signal by the laser 112. Therefore, the module, such as the clock and data recovery (CDR) circuit, the equalizer (EQ), the current-driven circuit or the like, that is included in the conventional laser drive circuit can be omitted. Therefore, the light-emitting power of the laser 112 can be reduced, and the power consumption of the electro-optical conversion unit 11 can be reduced.

Different from the related art, the effects of the present disclosure are as follows. By disposing the laser and the bias constant current source providing the constant current to the laser, the voltage signal to be transmitted can be directly converted into the optical signal. Therefore, a module, such as a clock and data recovery (CDR) circuit, an equalizer (EQ), a current-driven circuit or the like, that is included in a conventional laser drive circuit can be omitted. Therefore, the light-emitting power of the laser can be reduced, and the power consumption of the electro-optical conversion unit can be reduced.

The above descriptions are only some embodiments of the present disclosure, and are not intended to limit the scope of the present disclosure. Any equivalent structure or equivalent flow transformation made by using the contents of the specification and accompanying drawings of the present disclosure, or directly or indirectly applied to other related technical fields, is included in the scope of the patent protection of the present disclosure.

What is claimed is:

1. A photoelectric conversion module, comprising:
an electro-optical conversion unit, comprising a transmitting terminal, a laser, and a bias constant current source providing a constant current to the laser, wherein the laser is configured to convert a voltage signal to be transmitted on the transmitting terminal into an optical signal synchronized with the voltage signal to be transmitted.

2. The photoelectric conversion module according to claim 1, wherein the electro-optical conversion unit further comprises a capacitor element; and the capacitor element is disposed between the transmitting terminal and the laser, and configured to protect a signal source chip connected to the transmitting terminal.

3. The photoelectric conversion module according to claim 1, wherein the photoelectric conversion module further comprises:
a photoelectric conversion unit, comprising a receiving terminal, a photoelectric detector, and an electrical signal conversion unit connected to the photoelectric detector; wherein the photoelectric detector is configured to convert the optical signal received by the receiving terminal into a current signal, and the electrical signal conversion unit is configured to convert the current signal into a voltage signal.

4. The photoelectric conversion module according to claim 3, wherein the electrical signal conversion unit comprises a sampling resistor, and the sampling resistor is connected to the photoelectric detector and configured to convert the current signal generated by the photoelectric detector into a single ended voltage signal.

5. The photoelectric conversion module according to claim 4, wherein the electrical signal conversion unit further comprises a first element connected to the sampling resistor, and the first element is configured to convert the single ended voltage signal into a differential voltage signal.

6. The photoelectric conversion module according to claim 3, wherein the electrical signal conversion unit comprises a second element, and the second element is connected to the photoelectric detector and configured to directly convert the current signal output by the photoelectric detector into a differential voltage signal.

7. The photoelectric conversion module according to claim 6, wherein the second element comprises a transimpedance amplifier, an operational amplifier, a transistor, or a MOS transistor.

8. A photoelectric conversion device, comprising:
a photoelectric conversion module, comprising:
an electro-optical conversion unit, comprising a transmitting terminal, a laser, and a bias constant current source providing a constant current to the laser, wherein the laser is configured to convert a voltage signal to be transmitted on the transmitting terminal into an optical signal synchronized with the voltage signal to be transmitted.

9. The photoelectric conversion device according to claim 8, wherein the electro-optical conversion unit further comprises a capacitor element; and the capacitor element is disposed between the transmitting terminal and the laser, and configured to protect a signal source chip connected to the transmitting terminal.

10. The photoelectric conversion device according to claim 8, wherein the photoelectric conversion module further comprises:
a photoelectric conversion unit, comprising a receiving terminal, a photoelectric detector, and an electrical signal conversion unit connected to the photoelectric detector; wherein the photoelectric detector is configured to convert the optical signal received by the receiving terminal into a current signal, and the electrical signal conversion unit is configured to convert the current signal into a voltage signal.

11. The photoelectric conversion device according to claim 10, wherein the electrical signal conversion unit comprises a sampling resistor, and the sampling resistor is connected to the photoelectric detector and configured to convert the current signal generated by the photoelectric detector into a single ended voltage signal.

12. The photoelectric conversion device according to claim 11, wherein the electrical signal conversion unit further comprises a first element connected to the sampling resistor, and the first element is configured to convert the single ended voltage signal into a differential voltage signal.

13. The photoelectric conversion device according to claim 10, wherein the electrical signal conversion unit comprises a second element, and the second element is connected to the photoelectric detector and configured to directly convert the current signal output by the photoelectric detector into a differential voltage signal.

14. The photoelectric conversion device according to claim 13, wherein the second element comprises a transimpedance amplifier, an operational amplifier, a transistor, or a MOS transistor.

15. The photoelectric conversion device according to claim 8, wherein the photoelectric conversion device further comprises an integrated chip, and the integrated chip is connected to the transmitting terminal of the photoelectric conversion module; and the integrated chip is configured for transmitting the voltage signal to be transmitted to the transmitting terminal of the photoelectric conversion module, and receiving and processing the voltage signal generated by the photoelectric conversion module.

16. The photoelectric conversion device according to claim 15, wherein the photoelectric conversion module is integrated on a PCB board where the integrated chip is located, and the photoelectric conversion module is connected to the integrated chip through copper trace on the PCB board.

17. The photoelectric conversion device according to claim 15, wherein the photoelectric conversion module is integrated on a substrate to form a component with a photoelectric conversion function, and the component is disposed on a PCB board where the integrated chip is located by plugging or soldering.

18. The photoelectric conversion device according to claim 8, wherein the photoelectric conversion device further comprises an optical signal transmission channel, the optical signal transmission channel is connected to a receiving terminal of the photoelectric conversion module and configured for transmitting the optical signal, and the optical signal transmission channel comprises an optical fiber and an optical waveguide.

19. A photoelectric conversion method, comprising:
providing a photoelectric conversion module or a photoelectric conversion device comprising the photoelectric conversion module, wherein the photoelectric conversion module comprises:
an electro-optical conversion unit, comprising a transmitting terminal, a laser, and a bias constant current source providing a constant current to the laser, wherein the laser is configured to convert a voltage signal to be transmitted on the transmitting terminal into an optical signal synchronized with the voltage signal to be transmitted.

20. The photoelectric conversion method according to claim 19, wherein the electro-optical conversion unit further comprises a capacitor element; and the capacitor element is disposed between the transmitting terminal and the laser, and configured to protect a signal source chip connected to the transmitting terminal.
